(19) United States
(12) Patent Application Publication
(10) Pub. No.: US 2005/0050422 A1
(43) Pub. Date: Mar. 3, 2005

(54) Semiconductor integrated circuit

(76) Inventors: Noriko Jo, Itami-shi (JP); Takeshi Santo, Ibaraki-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/926,082

(22) Filed: Aug. 26, 2004

(30) Foreign Application Priority Data
Aug. 27, 2003 (JP) 2003-303541

(51) Int. Cl. G06F 11/00; G01R 31/28

(52) U.S. Cl. 714/735

(57) ABSTRACT

A semiconductor integrated circuit having a logic circuit comprises a plurality of test input terminals for giving test signals to the semiconductor integrated circuit; test circuits for receiving the inputted test signals, and testing the logic circuit using the test signals; a test output terminal for externally monitoring an output signal of the semiconductor integrated circuit; and an exclusive OR circuit for receiving output signals of the test circuits; wherein an output signal of the exclusive OR circuit is output from the test output terminal.

### FIELD OF THE INVENTION

The present invention relates to a semiconductor integrated circuit and, more particularly, to a test circuit for performing a burn-in test on a semiconductor integrated circuit.

### BACKGROUND OF THE INVENTION

Conventionally, a burn-in test for a semiconductor integrated circuit has been performed on a completed product that is packaged. Therefore, internal circuits of the integrated circuit are operated with signals supplied from several tens of scan input terminals, and the results of operations are outputted from several tens of scan output terminals. At this time, the output signals are continuously monitored to detect a point where a failure occurs during the burn-in test, i.e., so-called “monitor burn-in” has been carried out.

Hereinafter, the conventional burn-in test for a semiconductor integrated circuit will be described with reference to FIGS. 3(a) and 3(b).

FIG. 3(a) is a diagram for explaining the conventional burn-in test, and FIG. 3(b) is a diagram illustrating the inside of the semiconductor integrated circuit in detail.

In FIG. 3(a), reference numeral 1 denotes SCAN input terminals, 2 denotes SCAN output terminals, 10 denotes an LSI, and 11 denotes lead frames.

In FIG. 3(b), reference numeral 20 denotes SCAN chains (test circuits), 21 denotes SCAN input terminals, 22 denotes SCAN output terminals, 23 denotes flip-flops, 25 denotes combination circuits, and 26 denotes a logic circuit.

With reference to FIGS. 3(a) and 3(b), in the conventional burn-in test, burn-in test signals 100 are applied to the SCAN input terminals 1 (21) through a tester. In the LSI 10, the burn-in test signals 100 are stored in the flip-flops 23 by shift operation, and thereafter, the internal combination circuits 25 are operated by capture operation. Furthermore, operation result output signals 101 stored in the respective flip-flops 23 are successively output from the SCAN output terminals 2 (22) through the SCAN chains by shift operation, and the tester compares the output signals with an expected value which has been prepared by simulation or the like as to whether defects might occur during the burn-in test or not, thereby determining whether the LSI 10 is a defective or not.

In recent years, there has been employed a wafer-level burn-in test in which an LSI is tested in its wafer state before being packaged, because the wafer-level burn-in test has the advantage of cost reduction as compared with the ordinary burn-in test, for LSIs to be mass-produced.

FIG. 4(a) is a diagram for explaining the conventional wafer-level burn-in test for a semiconductor integrated circuit, and FIG. 4(b) is a diagram illustrating the inside of the semiconductor integrated circuit in detail.

With reference to FIG. 4(a), reference numeral 1 denotes SCAN input terminals, 3 denotes probes (bumps), 7 denotes SCAN output terminals to which the probes are assigned, 8 denotes SCAN output terminals to which no probes are assigned, and 10 denotes an LSI.

With reference to FIG. 4(b), reference numeral 20 denotes scan chains (test circuits), 21 denotes SCAN input terminals, 23 denotes flip-flops, 25 denotes combination circuits, 26 denotes a logic circuit, 29 denotes SCAN output terminals to which the probes are assigned, and 30 denotes SCAN output terminals to which no probes are assigned.

As shown in FIGS. 4(a) and 4(b), in contrast to the conventional burn-in test, since the LSI is not packaged, monitoring is performed not at the lead frames but at the SCAN output terminals (IO ports) 7 (29). Further, since the number of probes of a probe card used for the test is limited, no operation result output signals 102 are output from the SCAN output terminals 8 (30) to which no probes are assigned. Therefore, the smaller the chip size becomes, the less the SCAN output terminals can be monitored. That is, in the wafer-level burn-in test, the number of available probes is limited and, therefore, all of the SCAN output terminals cannot be monitored in contrast to the conventional burn-in test.

The above-mentioned conventional burn-in tests are disclosed in, for example, Japanese Published Patent Applications Nos. 2000-353783 and 2000-227458.

As described above, in the conventional wafer-level burn-in test for a semiconductor integrated circuit, since the number of available probes for one wafer is limited, the number of terminals to be assigned to the respective chips on the wafer becomes smaller with a decrease in the chip size, as compared with the burn-in test performed for completed products.

Therefore, in the wafer-level burn-in test, some of the output terminals are selected to be monitored while all of the output terminals are monitored in the burn-in test for completed products, leading to missing of defects in the terminals which are not monitored.

### SUMMARY OF THE INVENTION

The present invention is made to solve the above-mentioned problems and has for its object to provide a semiconductor integrated circuit in which all terminals can be monitored during a wafer-level burn-in test, thereby to detect all defects.

Other objects and advantages of the invention will become apparent from the detailed description that follows. The detailed description and specific embodiments described are provided only for illustration since various additions and modifications within the scope of the invention will be apparent to those of skill in the art from the detailed description.

According to a first aspect of the present invention, a semiconductor integrated circuit having a logic circuit comprises: a plurality of test input terminals for giving test signals to the semiconductor integrated circuit; test circuits for receiving the inputted test signals, and testing the logic circuit using the test signals; a test output terminal for externally monitoring an output signal of the semiconductor integrated circuit; and an exclusive OR circuit for receiving output signals of the test circuits; wherein an output signal of the exclusive OR circuit is output from the test output terminal. Therefore, the number of terminals for monitoring the output signals during the wafer-level burn-in test can be reduced, thereby simplifying the test. Further, since the probes which have been allocated to the plural output terminals for monitoring the output signals in the conventional wafer-level burn-in test can be allocated to the input/output terminals to which no probes have conventionally been allocated, defects at the input/output terminals to which no probes have conventionally been allocated can be detected without omission. Furthermore, since all of the output signals can be substantially monitored during the wafer-level burn-in test, whether the semiconductor integrated circuit is destroyed or normally operated can be checked by the wafer-level burn-in test before it is packaged, thereby eliminating the costs for packaging destroyed semiconductor integrated circuits.

According to a second aspect of the present invention, a semiconductor integrated circuit having a logic circuit comprises: a plurality of test input terminals for giving test signals to the semiconductor integrated circuit; test circuits for receiving the inputted test signals, and testing the logic circuit using the test signals; a test output terminal for externally monitoring an output signal of the semiconductor integrated circuit; a plurality of first exclusive OR circuits which are placed at plural sides of the semiconductor integrated circuit, and receive output signals of the test circuits; and a second exclusive OR circuit which receives the output signals of the test circuits and output signals of the first exclusive OR circuits; wherein an output signal of the second exclusive OR circuit is output from the test output terminal. Since the exclusive OR circuits are allocated to the places at plural sides of the semiconductor integrated circuit, complicated wiring in the layout of the semiconductor integrated circuit can be avoided and, furthermore, it becomes unnecessary to provide a lot of long lines from plural input terminals to plural output terminals in the semiconductor integrated circuit, thereby resolving the problems such as increases in circuit scale and power consumption due to insertion of a lot of cells against timing errors such as slew. Slew is rounding (tilting) of a signal waveform.

### BRIEF DESCRIPTION OF THE DRAWINGS

FIG. 1(a) is a diagram illustrating the construction of a semiconductor integrated circuit according to a first embodiment of the present invention, and FIG. 1(b) is a diagram illustrating the inside of the LSI in detail.

FIG. 2(a) is a diagram illustrating the construction of a semiconductor integrated circuit according to a second embodiment of the present invention, and FIG. 2(b) is a diagram illustrating the inside of the LSI in detail.

FIG. 3(a) is a diagram for explaining the conventional burn-in test for a semiconductor integrated circuit, and FIG. 3(b) is a diagram illustrating the inside of the LSI in detail.

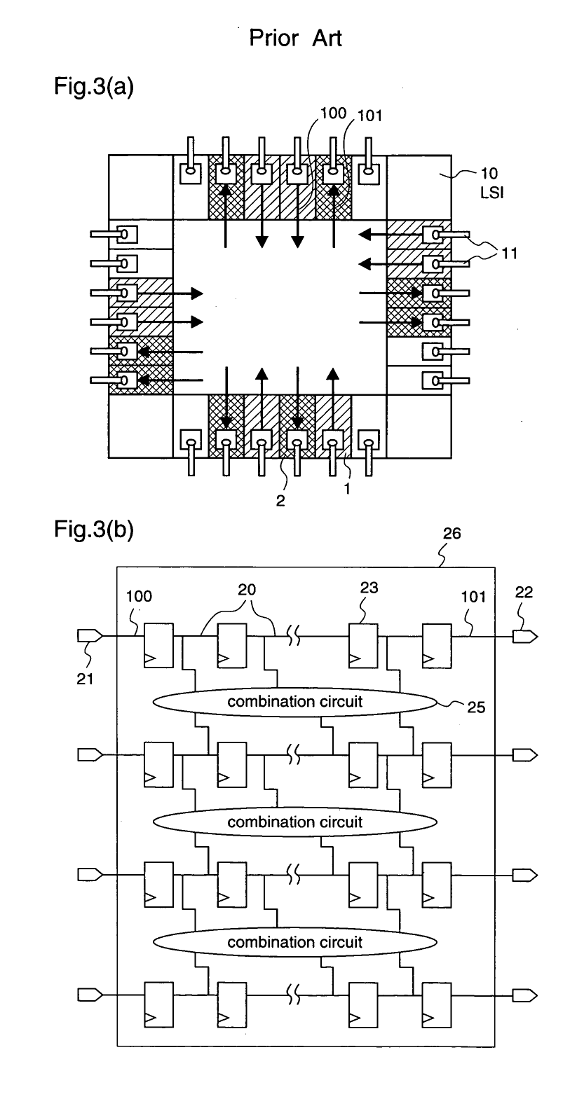

FIG. 4(a) is a diagram for explaining the conventional wafer-level burn-in test for a semiconductor integrated circuit, and FIG. 4(b) is a diagram illustrating the inside of the LSI in detail.

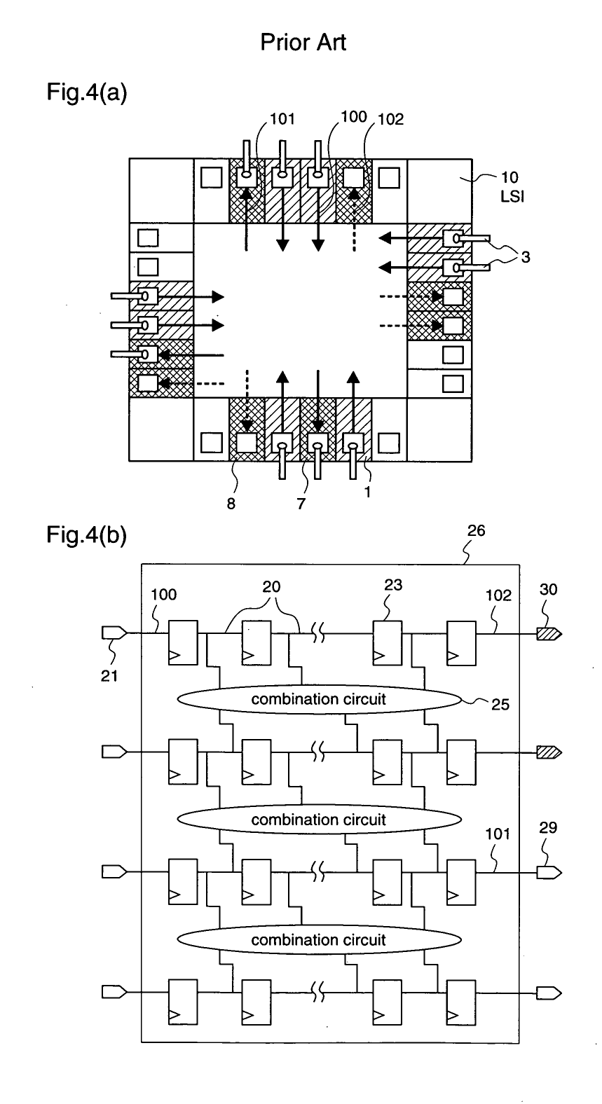

### DETAILED DESCRIPTION OF THE PREFERRED EMBODIMENTS

[Embodiment 1]

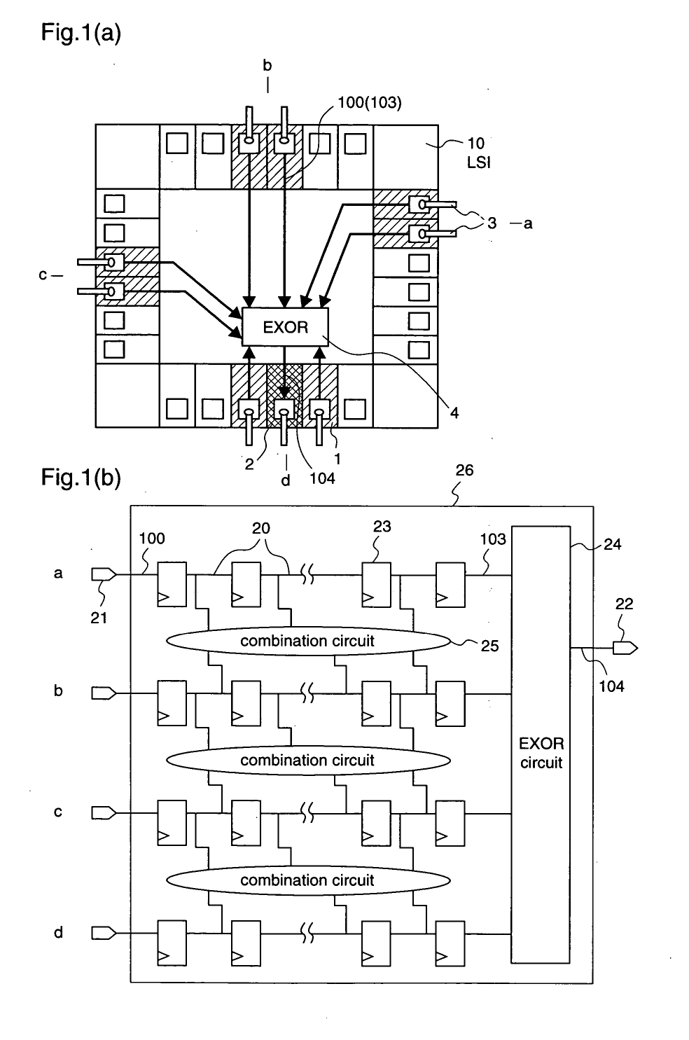

FIG. 1(a) is a diagram illustrating the construction of a semiconductor integrated circuit according to a first embodiment of the present invention, and FIG. 1(b) is a diagram illustrating the inside of the semiconductor integrated circuit in detail.

In FIG. 1(a), reference numeral 1 denotes SCAN input terminals, 2 denotes a SCAN output terminal, 3 denotes probes (bumps), 4 denotes an EXOR circuit (exclusive OR circuit), and 10 denotes an LSI.

In FIG. 1(b), 20 denotes SCAN chains (test circuits), 21 denotes SCAN input terminals, 22 denotes SCAN output terminals, 23 denotes flip-flops, 24 denotes an EXOR circuit, 25 denotes combination circuits, and 26 denotes a logic circuit.

Initially, an ordinary burn-in test is carried out. That is, as shown in FIGS. 1(a) and 1(b), burn-in test signals 100 are input to the SCAN input terminals 1 and 21 through the probes (bumps) 3, and desired signals among the inputted burn-in test signals 100 are stored in the flip-flops 23 by shift operation utilizing the SCAN chains (test circuits) 20, followed by capture operation. Then, all of operation result signals 103 to be output are input to the EXOR circuit 4 (24) which characterizes the present invention, and the output of the EXOR circuit 4 (24) is output as an operation result output signal 104 from the SCAN output terminal 2 (22) to be monitored at the probe (bump) 3 by the tester. When the operation result output signal 104 outputted from the SCAN output terminal 2 (22) is different from comparison data at the tester, it is judged that the LSI 10 is a defective. When the output 104 from the EXOR circuit 4 (24) to which all of the operation result signals 103 are input matches an expected value, it is determined that the LSI 10 is a non-defective. Furthermore, the EXOR circuit 4 (24) can realize the construction as follows. That is, when there are odd number of “1” among the N pieces of operation result signals 103 inputted to the EXOR circuit 4 (24), the EXOR circuit 4 (24) may output “0” as the operation result output signal 104. On the other hand, when there are even number of “1”, the EXOR circuit 4 (24) may output “1” as the operation result output signal 104. Therefore, when one of the N operation result signals 103 inputted to the EXOR circuit 4 (24) is a defective, i.e., when it is an inverse logic to the expected value, a signal different from the expected value is output from the EXOR circuit 4 (24), whereby a defective can be detected.

As described above, the semiconductor integrated circuit according to the first embodiment is provided with the plural SCAN input terminals 1 (21) for giving the burn-in test signals 100 to the semiconductor integrated circuit, the test circuits 20 for receiving the burn-in test signals 100 and testing the logic circuit 26, the SCAN output terminals 2 (22) for externally monitoring the output signals of the semiconductor integrated circuit, and the EXOR circuit 4 (24) for receiving the output result signals 103 of the test circuits 20, and the operation result output signal 104 from the EXOR circuit 4 (24) is outputted from the SCAN output terminal 2 (22). Therefore, the output signals from all of the output terminals existing in the semiconductor integrated circuit are substantially monitored, whereby all defects are detected without missing.

While in this first embodiment the EXOR circuit is employed, another logic circuit may be employed.

In the conventional method, N pieces of input signals are respectively given to the N pieces of scan chains, and N pieces of output signals must be monitored and compared to perform the burn-in test. In this first embodiment, however, N pieces of input signals are given to all of the SCAN chains, and one output signal is monitored and compared to execute the burn-in test. That is, the conventional method requires (2N) probes (bumps) while the invention method can test all the terminals with (N+1) probes (bumps). However, the output signal is not necessarily restricted to one.

[Embodiment 2]

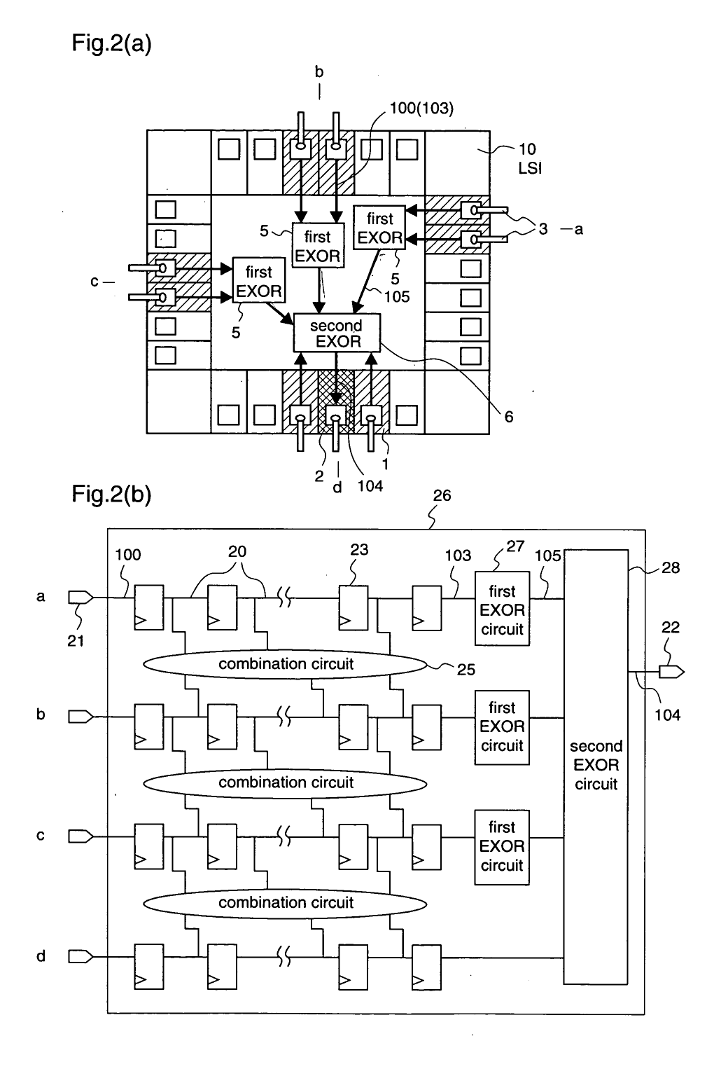

FIG. 2(a) is a diagram illustrating the construction of a semiconductor integrated circuit according to a second embodiment of the present invention, and FIG. 2(b) is a diagram illustrating the inside of the semiconductor integrated circuit in detail.

In FIG. 2(a), reference numeral 1 denotes SCAN input terminals, 2 denotes a SCAN output terminal, 3 denotes probes (bumps), 5 and 6 denote first and second EXOR circuits (exclusive OR circuits), and 10 denotes an LSI.

In FIG. 2(b), 20 denotes scan chains (test circuits), 21 denotes SCAN input terminals, 22 denotes a SCAN output terminal, 23 denotes flip-flops, 25 denotes combination circuits, 26 denotes a logic circuit, 27 denotes first EXOR circuits, and 28 denotes a second EXOR circuit.

As shown in FIGS. 2(a) and 2(b), burn-in test signals 100 are applied to the SCAN input terminals 1 (21), operation result signals 103 corresponding to the respective burn-in test signals 100 are input to the first EXOR circuits 5 (27), and the outputs of the first EXOR circuits 5 (27) are input to the second EXOR circuit 6 (28). To be specific, the operation result signals 105 from the first EXOR circuits 5 (27) which are placed at three sides (a,b,c) of the LSI 10 are input to the four-input second EXOR circuit 6 (28) which is placed at one side (d) of the LSI 10, and the operation result output signal 104 from the second EXOR circuit 6 (28) is output through the SCAN output terminal 2 (22).

As described above, the semiconductor integrated circuit according to the second embodiment is provided with the plural SCAN input terminals 1 (21) for giving the burn-in test signals 100 to the semiconductor integrated circuit, the test circuits 20 for receiving the burn-in test signals to perform a test for the logic circuit 26, the SCAN output terminal 2 (22) for externally monitoring the output signal from the semiconductor integrated circuit, a plurality of first EXOR circuits 5 (27) which are respectively arranged at plural sides of the semiconductor integrated circuit and receive the operation result signals 103 from the test circuits 20, and the second EXOR circuit 6 (28) which receives the operation result output signals 103 from the test circuits 20 and the operation result output signals 105 from the plural first EXOR circuits 5 (27). The operation result output signal 104 from the second EXOR circuit 6 (28) is output from the SCAN output terminal 2 (22). Therefore, it is possible to avoid complicated wiring due to an increase in the number of lines in the LSI, leading to reductions in the LSI scale and power consumption.

For example, in a large-scale LSI, a lot of long lines are laid in the LSI, resulting in complicated wiring. Further, there occurs a necessity for inserting buffers against slew errors or crosstalks in such long wiring, and the buffer cells cause an increase in the area of the LSI as well as an increase in power consumption.

In this second embodiment, however, the EXOR circuits 5 (27) are arranged at three sides (a,b,c) of the LSI while the EXOR circuit 6 (28) is arranged at one side (d) of the LSI, and the signals which are obtained from the side (d) at which the EXOR circuit 6 (28) is placed, and the signals which are obtained from the three sides (a,b,c) at which the EXOR circuits 5 (27) are placed and are combined to be input to the EXOR circuit 6 (28), are input together to the EXOR circuit 6 (28). Therefore, insertion of buffers as a countermeasure against timing errors such as slew is made to only the four lines 104 and 105 (refer to FIG. 2(a)), leading to reductions in the LSI scale and power consumption.

The EXOR circuits are not necessarily arranged at the four sides of the LSI.

1. A semiconductor integrated circuit having a logic circuit, comprising:
a plurality of test input terminals for giving test signals to the semiconductor integrated circuit;
test circuits for receiving the test signals supplied from the test input terminals, and testing the logic circuit using the test signals;
a test output terminal for externally monitoring an output signal of the semiconductor integrated circuit; and
an exclusive OR circuit for receiving output signals of the test circuits;
wherein an output signal of the exclusive OR circuit is output from the test output terminal.

2. A semiconductor integrated circuit having a logic circuit, comprising:
a plurality of test input terminals for giving test signals to the semiconductor integrated circuit;
test circuits for receiving the test signals supplied from the test input terminals, and testing the logic circuit using the test signals;
a test output terminal for externally monitoring an output signal of the semiconductor integrated circuit;
a plurality of first exclusive OR circuits which are placed at plural sides of the semiconductor integrated circuit, and receive output signals of the test circuits; and
a second exclusive OR circuit which receives the output signals of the test circuits and output signals of the first exclusive OR circuits;
wherein an output signal of the second exclusive OR circuit is output from the test output terminal.
